(19) United States
(12) Patent Application Publication
(10) Pub. No.: US 2025/0066405 A1
(43) Pub. Date: Feb. 27, 2025

(54) MOLYBDENUM PRECURSOR COMPOUND, METHOD FOR PREPARING SAME, AND METHOD FOR DEPOSITING MOLYBDENUM-CONTAINING FILM USING SAME

(71) Applicant: UP CHEMICAL CO., LTD., Pyeongtaek-si, Gyeonggi-do (KR)

(72) Inventors: Myeong Ho KIM, Pyeongtaek-si (KR); Jin Sik KIM, Pyeongtaek-si (KR); Jun Hwan CHOI, Pyeongtaek-si (KR)

(21) Appl. No.: 18/722,623

(22) PCT Filed: Dec. 23, 2022
(86) PCT No.: PCT/KR2022/021165

§ 371 Date: Jun. 21, 2024

(30) Foreign Application Priority Data
Dec. 24, 2021 (KR) 10-2021-0187252

(51) Int. Cl. C07F 17/00; C23C 16/18; C23C 16/455

(52) U.S. Cl. CPC C07F 17/00; C23C 16/18; C23C 16/45553

(57) ABSTRACT

The present invention relates to a molybdenum precursor compound, a composition for forming a molybdenum-containing film comprising same, a molybdenum-containing film formed by using same, and a method for depositing the molybdenum-containing film. The molybdenum precursor compound has a single structure and high purity, and thus can form a high-quality molybdenum-containing film, and has excellent thermal stability and low specific resistance, and thus may have various applications in the semiconductor field. In particular, since the molybdenum precursor compound can form a film having excellent coating properties and uniformity even on a substrate having patterns (grooves) on the surface, a porous substrate, a plastic substrate, or a substrate having a complex shape, a high-quality molybdenum-containing film can be easily realized.

### TECHNICAL FIELD

The present invention relates to a molybdenum precursor compound, a method for preparing the same, a precursor composition for forming a molybdenum-containing film comprising the same, a molybdenum-containing film using the same, and a method for depositing the same.

### BACKGROUND ART

Molybdenum-containing metal films, molybdenum-containing oxide films, molybdenum-containing carbide films, molybdenum-containing sulfide films, and molybdenum-containing nitride films can be used as diffusion barrier layers of metal wiring, gate metals, electrodes, and the like in a semiconductor process. They are widely used for industrial purposes as hard coating materials, sensors, channel layers, and catalysts.

For example, in order to be used as a capacitor electrode for next-generation electronic devices, especially, DRAM devices having a high step ratio, it is necessary to use a chemical vapor deposition (CVD) method or an atomic layer deposition (ALD) method that can achieve excellent step coverage on a highly irregular surface. This may require a liquid molybdenum zero-valent precursor compound. In particular, a low-resistance liquid molybdenum zero-valent precursor compound is needed for use in three-dimensional NAND gates.

Meanwhile, examples of molybdenum precursor compounds currently in use include bis-toluene-molybdenum ((η⁶-MeC₆H₅)₂Mo) and bis-ethylbenzene-molybdenum ((η⁶-EtC₆H₅)₂Mo).

However, since bis-toluene-molybdenum ((η⁶-MeC₆H₅)₂Mo) is a solid at normal temperature and pressure, it is difficult to supply its source in a process, and there may be difficulties in the process of dismounting and remounting the container containing a solid precursor. In addition, there may be a problem in that mass productivity is significantly reduced in the mass production of semiconductor devices using the compound.

In addition, although a bis-ethylbenzene-molybdenum ((η⁶-EtC₆H₅)₂Mo) precursor compound is a liquid at room temperature, it is in a mixture structure rather than a single compound, which causes a limit to increasing its purity, and it is difficult to maintain the same composition during synthesis. Thus, it may be difficult to provide a uniform, high-quality molybdenum-containing film in the mass production of semiconductor devices due to non-uniformity in composition.

Accordingly, there is a need to develop a liquid molybdenum precursor compound that is suitable for process temperatures for various applications such as memory and non-memory fields, can be used for CVD and/or ALD, and has a single structure and excellent purity to form a uniform and high-quality molybdenum-containing film.

### PRIOR ART DOCUMENTS

### Patent documents

(Patent Document 1) Korean Laid-open Patent Publication No. 2020-0091469

### DISCLOSURE OF INVENTION

### Technical Problem

The present invention has been devised to solve the problems of the prior art.

An object of the present invention is to provide a novel molybdenum precursor compound that has a single structure, is advantageous for the manufacturing process since it is in a liquid state at room temperature, is capable of forming a molybdenum-containing film having a uniform thickness and excellent quality by atomic layer deposition (ALD) since it is excellent in thermal stability, and is capable of lowering the resistivity value of the molybdenum-containing film to an optimal range.

Another object of the present invention is to provide a method for preparing the molybdenum precursor compound in a safe and efficient manner.

Still another object of the present invention is to provide a composition for forming a molybdenum-containing film comprising the molybdenum precursor compound.

Still another object of the present invention is to provide a molybdenum-containing film having a uniform thickness and excellent quality even on various substrates by using the molybdenum precursor compound.

Still another object of the present invention is to provide a method for depositing a molybdenum-containing film, in which the molybdenum-containing film is deposited using the molybdenum precursor compound.

However, the problems to be solved by the present invention are not limited to those mentioned above, and other problems not mentioned will be clearly understood by those skilled in the art from the following description.

### Solution to Problem

The present invention provides a molybdenum precursor compound represented by the following Formula 1:

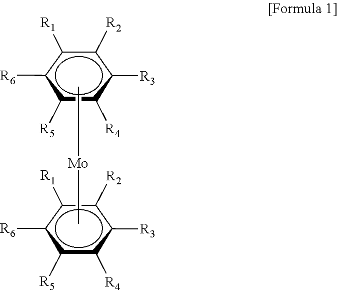

In Formula 1,

R₁ to R₆ are each independently selected from the group consisting of hydrogen and a linear or branched C₁-C₈ alkyl group,
provided that at least two of R₁ to R₆ are not hydrogen.

In addition, the present invention provides a composition for forming a molybdenum-containing film, which comprises the molybdenum precursor compound.

In addition, the present invention provides a molybdenum-containing film formed using the molybdenum precursor compound.

Further, the present invention provides a method for depositing a molybdenum-containing film, which comprises depositing a molybdenum-containing film on a substrate using the molybdenum precursor compound.

### Advantageous Effects of Invention

The molybdenum precursor compound according to an embodiment of the present invention has a single structure and is excellent in purity, so that a molybdenum-containing film of excellent quality can be formed. In addition, it is advantageous for the manufacturing process since it is in a liquid state at room temperature, is capable of readily forming a molybdenum-containing film by chemical vapor deposition (CVD) or atomic layer deposition (ALD) since it is excellent in thermal stability, and can be utilized in DRAM or NAND flashes, upper and lower electrodes and gate electrodes of capacitors used in logic devices, and the like that require low resistivity since it is possible to lower its resistivity value to an optimal range.

Further, it is possible to form a uniform film with excellent coverage even on a substrate having irregularities or patterns (grooves) on its surface, a porous substrate, a plastic substrate, or a substrate having a complex shape in a three-dimensional structure, whereby it is possible to achieve a molybdenum-containing film of high quality.

### BRIEF DESCRIPTION OF DRAWINGS

FIG. 1 shows ¹H-NMR spectra of the molybdenum precursor compounds prepared according to Examples 1 and 3 of the present application and Comparative Example 2.

FIG. 2 is a graph showing the results of thermogravimetric analysis (TGA) measurement of the molybdenum precursor compounds of Examples 1 and 3 of the present application and Comparative Example 1.

FIG. 3 is a transmission electron microscope (TEM) photograph of a molybdenum-containing nitride film formed using the molybdenum precursor compound prepared in Example 1 of the present application and ammonia (NH₃) by an ALD method with respect to temperature.

FIG. 4 is a graph showing the resistivity values of a molybdenum-containing nitride film formed using the molybdenum precursor compound prepared in Example 1 of the present application and ammonia (NH₃) by an ALD method with respect to temperature.

FIG. 5 is a TEM photograph of a molybdenum-containing nitride film formed using the molybdenum precursor compound prepared in Example 1 of the present application and ammonia (NH₃) plasma by a PEALD method with respect to temperature.

FIG. 6 is a graph showing the deposition rate and resistivity values of a molybdenum-containing nitride film formed using the molybdenum precursor compound prepared in Example 1 of the present application and ammonia (NH₃) plasma by a PEALD method with respect to temperature.

FIG. 7 is a graph showing the element content (%) of a molybdenum-containing nitride film formed at 350° C. using the molybdenum precursor compound prepared in Example 1 of the present application and ammonia (NH₃) plasma by a PEALD method when measured by Auger electron spectroscopy (AES).

FIG. 8 is a graph showing the element content (%) of a molybdenum-containing nitride film formed at 400° C. using the molybdenum precursor compound prepared in Example 1 of the present application and ammonia (NH₃) plasma by a PEALD method when measured by AES.

FIG. 9 is a graph showing the element content (%) of a molybdenum-containing nitride film formed at 450° C. using the molybdenum precursor compound prepared in Example 1 of the present application and ammonia (NH₃) plasma by a PEALD method when measured by AES.

FIG. 10 is a TEM photograph of a molybdenum-containing nitride film formed using the molybdenum precursor compound prepared in Comparative Example 2 and ammonia (NH₃) plasma by a PEALD method with respect to temperature.

FIG. 11 is a graph showing the element content (%) of a molybdenum-containing nitride film formed at 350° C. using the molybdenum precursor compound prepared in Comparative Example 2 and ammonia (NH₃) plasma by a PEALD method when measured by AES.

FIG. 12 is a graph showing the element content (%) of a molybdenum-containing nitride film formed at 400° C. using the molybdenum precursor compound prepared in Comparative Example 2 and ammonia (NH₃) plasma by a PEALD method when measured by AES.

FIG. 13 is a graph showing the element content (%) of a molybdenum-containing nitride film formed at 450° C. using the molybdenum precursor compound prepared in Comparative Example 2 and ammonia (NH₃) plasma by a PEALD method when measured by AES.

### BEST MODE FOR CARRYING OUT THE INVENTION

Hereinafter, the present application will be described in more detail.

The advantages and features of the present invention and the methods of achieving them will become apparent with reference to the embodiments described hereinafter. However, the present invention is not limited to the embodiments described below, but may be embodied in various different forms. These embodiments are provided so that the disclosure of the present invention will be thorough and complete, and will fully convey the scope of the invention to those skilled in the art. The invention is defined by only the scope of the claims.

In addition, in the present specification, in the case where an element is mentioned to be formed “on” another element, it means not only that one element is directly formed “on” another element, but also that other element(s) is interposed between them.

In the present specification, when a part is referred to as “comprising” an element, it is to be understood that the part may comprise other elements as well, rather than exclude other elements, unless otherwise indicated.

All numbers and expressions related to the quantities of components, reaction conditions, and the like used herein are to be understood as being modified by the term “about,” unless otherwise indicated.

In the present specification, each of the terms “film” and “thin film” refers to both “film” and “thin film,” unless otherwise specified.

In the present specification, the term “alkyl” or “alkyl group” covers linear or branched alkyl groups and all possible isomers thereof. For example, the alkyl group may be a methyl group (Me), an ethyl group (Et), a n-propyl group (ⁿPr), an iso-propyl group (ⁱPr), a n-butyl group (^{s}Bu) group, a tert-butyl group (^{t}Bu), an iso-butyl group (ⁱBu), a sec-butyl group (^{s}Bu), a pentyl group, a hexyl group, an iso-hexyl group, a heptyl group, a 4,4-dimethylpentyl group, an octyl group, a 2,2,4-trimethylpentyl group, a nonyl group, a decyl group, and isomers thereof, but it is not limited thereto.

### Molybdenum Precursor Compound

According to an embodiment of the present invention, there is provided a molybdenum precursor compound represented by the following Formula 1:

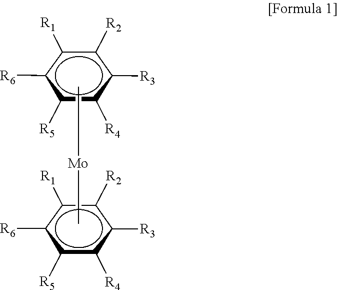

In Formula 1,

R₁ to R₆ are each independently selected from the group consisting of hydrogen and a linear or branched C₁-C₈ alkyl group,
provided that at least two of R₁ to R₆ are not hydrogen.

The molybdenum precursor compound has a single structure having one composition when analyzed by ¹H-NMR, has high purity, is advantageous for the manufacturing process since it is in a liquid state at room temperature, and is capable of readily forming a molybdenum-containing film by chemical vapor deposition (CVD) as well as atomic layer deposition (ALD) since it is excellent in thermal stability.

In particular, in the case where a molybdenum-containing film is formed using the molybdenum precursor compound, it can provide a low resistivity (μΩ·cm) value of, for example, 1,200 μΩ·cm or less; thus, it can be widely used as a gate electrode, a diffusion barrier layer, and a capacitor electrode used in DRAM or NAND flashes and logic devices that require low resistivity.

In addition, it is possible to form a uniform film with excellent coverage even on a substrate having irregularities or patterns (grooves) on its surface, a porous substrate, a plastic substrate, or a substrate having a complex shape in a three-dimensional structure, whereby it is possible to provide a molybdenum-containing film of high quality. The molybdenum precursor compound has technical significance in that it can be advantageously used in various applications in the field of electronic devices, as well as it can exhibit excellent characteristics.

According to an embodiment of the present invention, in Formula 1, R₁ to R₆ are each independently selected from hydrogen, methyl, ethyl, propyl, isopropyl, butyl, isobutyl, tert-butyl, and pentyl, provided that at least two of R₁ to R₆ are not hydrogen.

In addition, R₁ to R₆ are unsubstituted or substituted C₁-C₆ alkyl groups, wherein the substituents may each independently comprise a C₁-C₆ alkyl group, a C₂-C₆ alkenyl group, a C₂-C₆ alkynyl group, and a C₁-C₆ alkoxy group. For example, the substituents may each independently comprise a C₁-C₆ alkyl group, a C₁-C₄ alkyl group, or a C₁-C₂ alkyl group.

Specifically, the molybdenum precursor compound may be a compound represented by any one of the following Formulae 1-1 to 1-3.

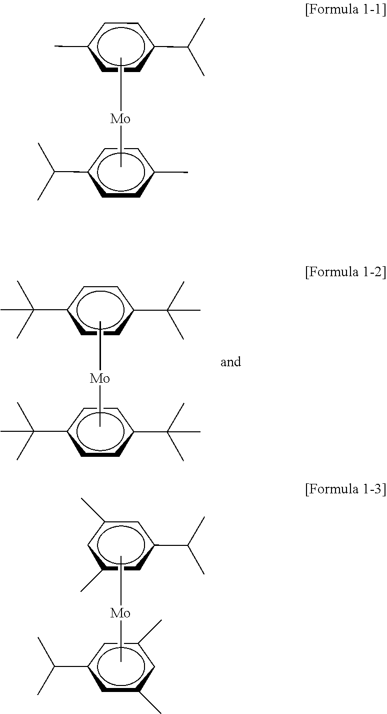

The molybdenum precursor compound according to an embodiment of the present invention has excellent thermal stability, can be applied at, for example, 300° C. to 550° C., and is present in a liquid state at room temperature, whereby it is possible to form a molybdenum-containing film by ALD as well as CVD. In particular, the molybdenum precursor compound has a huge advantage in that it can readily deposit molybdenum-containing metal films, molybdenum-containing oxide films, molybdenum-containing carbide films, molybdenum-containing sulfide films, and molybdenum-containing nitride films having uniform and excellent film characteristics in an atomic layer unit by ALD.

The molybdenum precursor compound has a TG₅₀ (° C.) of, for example, 180° C. to 350° C., for example, 180° C. to 300° C., for example, 180° C. to 250° C., for example, 190° C. to 300° C., for example, 200° C. to 300° C., for example, 200° C. to 280° C., or, for example, 200° C. to 250° C., wherein TG₅₀ is a temperature when the weight of the molybdenum precursor compound is reduced by 50% while it is heated from room temperature to 500° C. at a temperature elevation rate of 10° C./minute in thermogravimetric analysis (TGA).

According to an embodiment of the present invention, the molybdenum precursor compound has a residual weight (W₅₀₀) at 500° C. of, for example, 36% by weight or less, for example, 35% by weight or less, for example, 30% by weight or less, for example, 20% by weight or less, for example, 15% by weight or less, for example, 10% by weight or less, for example, 8% by weight or less, for example, 7% by weight or less, for example, 5% by weight or less, for example, 4.5% by weight or less, for example, 3% by weight or less, for example, 2% by weight or less, for example, 1.5% by weight or less, for example, 1.2% by weight or less, for example, 1% by weight or less, for example, 0.7% by weight or less, or, for example, 0.6% by weight or less as measured by thermogravimetric analysis (TGA).

Specifically, the molybdenum precursor compound has a residual weight (W₅₀₀) at 500° C. of 1.5% by weight or less as measured by thermogravimetric analysis (TGA).

According to an embodiment of the present invention, the molybdenum precursor compound may have a weight residual ratio (WR₅₀₀) of 70% or more according to the following Equation 1.

$$Weight residual ratio ( {WR}_{500} , \% ) = \frac{{W}_{25} - {W}_{500}}{{W}_{25}} \times 100 \qquad [ Equation 1 ]$$

In Equation 1,
W₂₅ is the initial weight (wt %) of the molybdenum precursor compound at 25° C., and
W₅₀₀ is the weight (wt %) of the molybdenum precursor compound at 500° C. as the temperature is raised from 25° C. to 500° C. at a temperature elevation rate of 10° C./minute.

Specifically, the molybdenum precursor compound may have a weight residual ratio (WR₅₀₀) of, for example, 72% by weight or more, for example, 75% by weight or more, for example, 80% by weight or more, for example, 85% by weight or more, for example, 87% by weight or more, for example, 88% by weight or more, for example, 89% by weight or more, for example, 90% by weight or more, for example, 92% by weight or more, for example, 93% by weight or more, for example, 95% by weight or more, for example, 97% by weight or more, for example, 98% by weight or more, or, for example, 99% by weight or more. If the molybdenum precursor compound has a weight residual ratio (WR₅₀₀) satisfying the above range, it has excellent volatility, so that it may be more advantageous for forming at least one selected from the group consisting of molybdenum-containing metal films, molybdenum-containing oxide films, molybdenum-containing carbide films, molybdenum-containing sulfide films, and molybdenum-containing nitride films at a temperature range of, for example, 300° C. or higher, specifically 300 to 550° C., for example, 350° C. to 550° C. In particular, it has a huge advantage in that it is possible to achieve uniform and excellent film characteristics in an atomic layer unit by ALD. [86]

### Method for Preparing a Molybdenum Precursor Compound

According to an embodiment of the present invention, there is provided a method for preparing a molybdenum precursor compound represented by the following Formula 1.

The molybdenum precursor compound represented by Formula 1 may be prepared by various methods.

The method for preparing a molybdenum precursor compound represented by Formula 1 according to an embodiment of the present invention comprises reacting a compound represented by the following Formula A with a compound represented by the following Formula B:

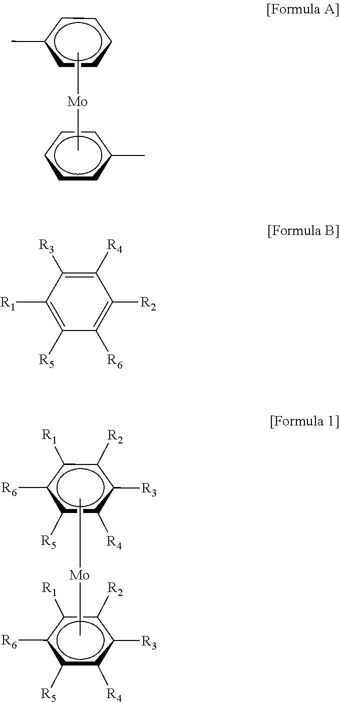

In Formula B and Formula 1,
R₁ to R₆ are each independently selected from the group consisting of hydrogen and a linear or branched C₁-C₈ alkyl group,
provided that at least two of R₁ to R₆ are not hydrogen.

Specifically, a molybdenum precursor compound represented by Formula 1 may be prepared by a reaction as shown in the following Reaction Scheme 1.

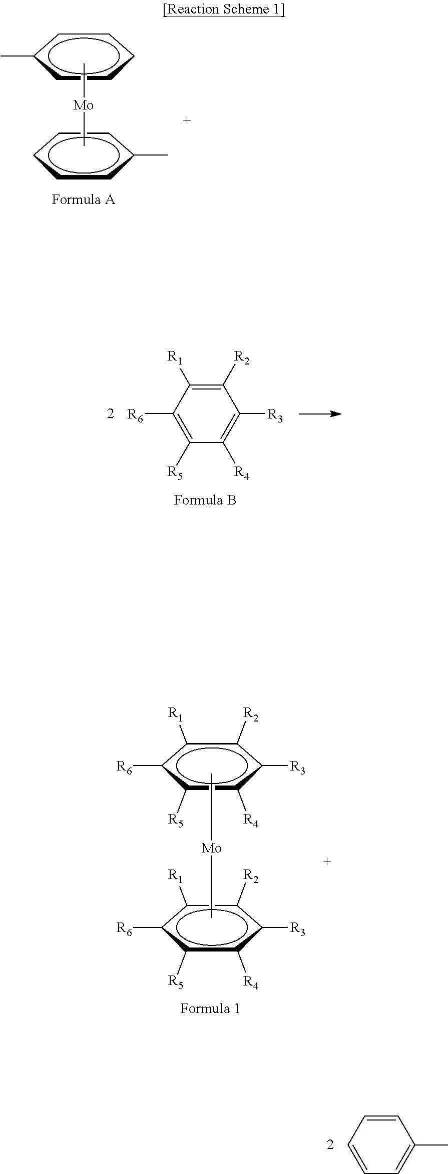

In Reaction Scheme 1,
R₁ to R₆ are each as defined above.

As shown in Reaction Scheme 1, the molybdenum precursor compound of Formula 1 can be readily obtained by reacting the compound represented by Formula A with the compound represented by Formula B and then purifying the resultant. In particular, the compound represented by Formula 1 prepared as in Reaction Scheme 1 may have a single structure and may be a liquid compound of high purity.

The molar ratio of the compound represented by Formula A to the compound represented by Formula B may be 1:2 to 50, 1:2 to 40, 1:2 to 30, or 1:2 to 20.

The reaction may be carried out at 150° C. or higher for 5 hours or longer.

Specifically, the compound represented by Formula A and the compound represented by Formula B are placed in a flask and maintained at room temperature. A cooler is connected to the flask, and the mixture in the flask is heated to, for example, about 150° C. or higher, specifically about 160° C. to 300° C., and then reacted for, for example, 5 hours or longer, specifically 8 to 20 hours, to obtain the compound represented by Formula 1. In addition, upon completion of the reaction, the salt formed during the reaction may be removed through filtration or the like, and the solvent and volatile side reactants may be distilled under a reduced pressure.

### Composition for Forming a Molybdenum-Containing Film

According to an embodiment of the present invention, there is provided a composition for forming a molybdenum-containing film, which comprises the molybdenum precursor compound represented by Formula 1.

The composition may further comprise an oxygen source comprising at least one selected from the group consisting of water vapor (H₂O), oxygen (O₂), oxygen plasma (O₂ plasma), nitric oxide (NO, N₂O), nitric oxide plasma (N₂O plasma), oxygen nitride (N₂O), hydrogen peroxide (H₂O), and ozone (O₃); and a nitrogen source comprising at least one selected from the group consisting of nitrogen (N₂), ammonia (NH₃), ammonia plasma (NH₃ plasma), hydrazine (N₂H₄), and nitrogen plasma (N₂ plasma). In addition, the composition may further comprise hydrogen (H₂).

Specifically, the composition may comprise, for example, at least one selected from the group consisting of hydrogen (H₂), nitrogen (N₂), and ammonia (NH₃).

The composition may comprise, for example, at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O), hydrogen peroxide (H₂O), and ozone (O₃).

The composition may comprise, for example, at least one selected from the group consisting of ammonia (NH₃), ammonia plasma (NH₃ plasma), hydrazine (N₂H₄), and nitrogen plasma (N₂ plasma).

More specifically, the composition may comprise at least one selected from the group consisting of hydrogen (H₂), ozone (O₃), and ammonia (NH₃).

### Molybdenum-Containing Film

According to an embodiment of the present invention, there may be provided a molybdenum-containing film formed using the molybdenum precursor compound represented by Formula 1.

The molybdenum-containing film may have a thickness of several nanometers (nm) to several micrometers (μm) and may be variously applied depending on the application purposes.

For example, the thickness of the molybdenum-containing film may be about 1 nm or more, about 5 nm or more, about 10 nm or more, about 15 nm or more, about 20 nm or more, about 25 nm or more, about 30 nm or more, about 35 nm or more, about 40 nm or more, about 45 nm or more, or about 50 nm or more. In addition, the thickness of the molybdenum-containing film may be about 500 nm or less, about 450 nm or less, about 400 nm or less, about 350 nm or less, about 300 nm or less, about 250 nm or less, about 200 nm or less, about 150 nm or less, or about 100 nm or less. Specifically, the thickness of the molybdenum-containing film may be variously selected from about 1 nm to about 500 nm.

The molybdenum-containing film may be formed on a substrate (or board).

The substrate may be a molybdenum semiconductor wafer, a compound semiconductor wafer, and plastic boards (PI, PET, and PES), but it is not limited thereto. A substrate having holes or grooves may be used, and a porous substrate having a large surface area may be used.

As the molybdenum precursor compound according to an embodiment of the present invention has a specific structure of Formula 1, it has a low density and high thermal stability, which allows a molybdenum-containing film to be efficiently formed in various temperature ranges by CVD and ALD. In particular, it is possible to uniformly form a molybdenum-containing film even on a substrate having patterns (grooves) or fine irregularities on its surface, a porous substrate, or a plastic substrate having a thickness of several micrometers to several tens nanometers in a temperature range of 300° C. to 550° C.

According to an embodiment of the present invention, the molybdenum-containing film may be formed on a substrate comprising irregularities or patterns (grooves) having an aspect ratio of 1 to 50 and a width of 1 μm to 10 nm or less.

Specifically, the aspect ratio may be about 1 or more, about 2 or more, about 3 or more, about 5 or more, about 7 or more, about 10 or more, or about 15 or more. In addition, the aspect ratio may be about 50 or less, about 45 or less, about 40 or less, about 35 or less, about 30 or less, about 25 or less, or about 20 or less.

In addition, the width may be about 10 nm or more, about 15 nm or more, about 20 nm or more, about 25 nm or more, about 30 nm or more, about 35 nm or more, or about 40 nm or more. In addition, the width may be about 1 μm or less, about 900 nm or less, about 800 nm or less, about 700 nm or less, about 600 nm or less, about 500 nm or less, or about 450 nm or less.

The molybdenum-containing film may be at least one selected from the group consisting of a molybdenum-containing metal film, a molybdenum-containing oxide film, a molybdenum-containing carbide film, a molybdenum-containing sulfide film, and a molybdenum-containing nitride film.

In addition, the molybdenum-containing film according to an embodiment of the present invention may have a low resistivity (μΩ·cm) of 1,200 μΩ·cm or less.

The molybdenum-containing film may have different resistivities depending on temperature.

Specifically, the resistivity of the molybdenum-containing film at about 350° C. may be, for example, 400 to 1,200 μΩ·cm, for example, 450 to 1,200 μΩ·cm, for example, 500 to 1,200 μΩ·cm, for example, 600 to 1,200 μΩ·cm, or for example, 700 to 1,200 μΩ·cm.

As another example, the resistivity of the molybdenum-containing film at about 400° C. may be, for example, 400 to 1,200 μΩ·cm, for example, 400 to 1,000 μΩ·cm, for example, 400 to 900 μΩ·cm, for example, 400 to 800 μΩ·cm, or, for example, 500 to 800 μΩ·cm.

As still another example, the resistivity of the molybdenum-containing film at about 450° C. may be, for example, 400 to 1,200 μΩ·cm, for example, 400 to 900 μΩ·cm, for example, 300 to 800 μΩ·cm, for example, 300 to 700 μΩ·cm, for example, 300 to 600 μΩ·cm, or, for example, 300 to 500 μΩ·cm.

As still another example, the resistivity of the molybdenum-containing film at about 500° C. may be, for example, 300 to 1,200 μΩ·cm, for example, 300 to 1,000 μΩ·cm, for example, 300 to 900 μΩ·cm, for example, 300 to 800 μΩ·cm, or, for example, 300 to 700 μΩ·cm.

Thus, the molybdenum-containing film can be used as a gate electrode, a diffusion barrier layer, and a capacitor electrode used in DRAM or NAND flashes and logic devices that require low resistivity, and it can be variously applied depending on the application purposes.

### Method for Depositing a Molybdenum-Containing Film

According to an embodiment of the present invention, there is provided a method for depositing a molybdenum-containing film, which comprises depositing a molybdenum-containing film on a substrate (board) using the molybdenum precursor compound represented by Formula 1.

Specifically, it may comprise supplying the molybdenum precursor compound represented by Formula 1 or the composition for forming a molybdenum-containing film in a gaseous state to form a molybdenum-containing film on a substrate, but it is not limited thereto.

The substrate is as described above.

The deposition method of a film may use any methods and/or apparatuses known in the art; if necessary, it may be carried out using one or more additional reactant gases or the like.

According to an embodiment of the present invention, in the method for depositing a molybdenum-containing film, a substrate is accommodated in a reaction chamber, and the molybdenum precursor compound is then transferred onto the substrate using a transport gas or a diluent gas to deposit the molybdenum-containing film.

Specifically, the deposition may be carried out at a temperature of 300° C. to 550° C., 350° C. to 550° C., 350° C. to 500° C., or 350° C. to 450° C., by chemical vapor deposition (CVD), specifically organometallic chemical vapor deposition (MOCVD), or atomic layer deposition (ALD).

In addition, the atomic layer deposition may comprise a plasma enhanced atomic layer deposition (PEALD).

In particular, it is possible to uniformly form a molybdenum-containing film even on a substrate having patterns (grooves) on its surface, a porous substrate, or a plastic substrate in a temperature range of 300° C. to 550° C. It is possible to form a uniform film on the substrate, covering the deepest surface of fine patterns (grooves) and the upper surface of the fine patterns (grooves) having an aspect ratio of about 1 to 50 or more and a width of 1 μm to 10 nm or less.

Here, the deposition carried out at the above temperature allows it to be applied to memory devices, logic devices, and display devices. Since the process temperature is broad, the deposition is preferably conducted in the above deposition temperature in order to be applicable to various fields.

In addition, it is preferable to use at least one mixed gas selected from the group consisting of argon (Ar), nitrogen (N₂), helium (He), and hydrogen (H₂) as the transport gas or diluent gas.

In addition, the method of delivering the molybdenum precursor compound onto the substrate may be at least one method selected from the group consisting of a bubbling method in which the molybdenum precursor compound is forcibly vaporized using a transport gas or a diluent gas, a liquid delivery system (LDS) method for supplying it in a liquid phase at room temperature to be vaporized through a vaporizer; a vapor flow control (VFC) method for directly supplying the precursor using its vapor pressure; and a bypass method.

For example, if the vapor pressure is high, a vapor flow control (VFC) method may be used. If the vapor pressure is low, at least one supply method selected from the group consisting of a bypass method of vaporization by heating the vessel; and a method of bubbling using argon (Ar) or nitrogen (N₂) gas may be used.

More specifically, the delivery method comprises a bubbling method or a bypass method of vaporization by heating, in which the bubbling method may be carried out using a transport gas in a temperature range of 100° C. to 150° C. and 0.1 to 10 Torr, and the bypass method of vaporization by heating may be carried out using a vapor pressure of 0.1 to 1.5 Torr in a temperature range of room temperature to 100° C.

In addition, in order to vaporize the molybdenum precursor compound, for example, argon (Ar) or nitrogen (N₂) gas may be used for the transportation thereof, thermal energy or plasma may be used during deposition, or a bias may be applied on the substrate.

Meanwhile, in order to deposit a molybdenum-containing metal film during the deposition of a film, at least one selected from the group consisting of hydrogen (H₂), neutral nitrogen (N₂), and ammonia (NH₃) may be used as a reaction gas.

In addition, in order to deposit a molybdenum-containing oxide film during the deposition of a film, at least one selected from the group consisting of water vapor (H₂O), oxygen (O₂), oxygen plasma (O₂ plasma), nitric oxide (NO, N₂O), nitric oxide plasma (N₂O plasma), oxygen nitrate (N₂O), hydrogen peroxide (H₂O), and ozone (O₃) may be used as a reaction gas.

In addition, in order to deposit, for example, a molybdenum-containing nitride film during the deposition of a film, at least one selected from the group consisting of ammonia (NH₃), ammonia plasma (NH₃ plasma), hydrazine (N₂H₄), and nitrogen plasma (N₂ plasma) may be used as a reaction gas.

### MODE FOR THE INVENTION

Hereinafter, the present invention will be described in detail with reference to examples. The following examples are only illustrative of the present invention, and the scope of the present invention is not limited thereto.

### EXAMPLE

### <Example 1> Preparation of bis-4-isopropyltoluene-molybdenum: (η⁶-4-ⁱPr-MeC₆H₄)₂Mo

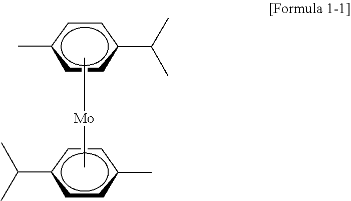

A flame-dried 2-liter Schlenk flask was charged with about 88 g (0.31 mole) of bis-toluene-molybdenum ((η⁶-MeC₆H₅)₂Mo) represented by Formula 1-4 of Comparative Example 1 described below and about 1,000 ml of 4-isopropyltoluene (C₁₀H₁₄), which was maintained at room temperature. A cooler was connected to the flask, and the mixture in the flask was heated to 180° C. and then stirred for 12 hours. Upon completion of the reaction, the salt formed during the reaction was removed through filtration, and the solvent and volatile side reactants were distilled off under a reduced pressure to obtain about 120 g (yield: about 60% based on MoCl₅) of a green liquid represented by Formula 1-1.

Density: 1.28 g/mole (at 25° C.)

Boiling point (bp): 105° C. (0.4 Torr) (308.6° C. at 760 mmHg)

¹H-NMR (400 MHz, C₆D₆, 25° C.): δ4.56 (s, 8H, Mo((CH₃)₂CH—C₆H₄—CH₃)), δ2.46, 2.28, 2.26 (m, 2H, Mo((CH₃)₂CH—C₆H₄—CH₃)), δ1.96 (s, 6H, Mo((CH₃)₂CH—C₆H₄—CH₃)), δ1.17, 1.15 (d, 12H, Mo((CH₃)₂CH—C₆H₄—CH₃))

### <Example 2> Preparation of bis-1,4-di-tertiary-butylbenzene-molybdenum: (η⁶-1,4-(^{t}Bu)₂C₆H₄)₂Mo

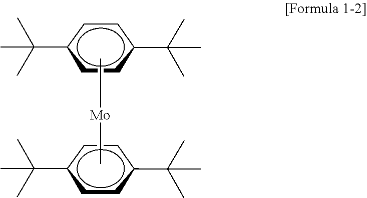

A flame-dried 2-liter Schlenk flask was charged with about 29 g (0.1 mole) of bis-toluene-molybdenum ((η⁶-MeC₆H₅)₂Mo) represented by Formula 1-4 of Comparative Example 1 described below and about 250 g of 1,4-di-tert-butylbenzene (C₁₄H₂₂), which was maintained at room temperature. A cooler was connected to the flask, and the mixture in the flask was heated to 180° C. and then stirred for 12 hours. Upon completion of the reaction, the salt formed during the reaction was removed through filtration, and the solvent and volatile side reactants were distilled off under a reduced pressure to obtain about 30 g (yield: about 60% based on MoCl₅) of a green solid represented by Formula 1-2.

Boiling point (bp): 130° C. (0.4 Torr) (343.6° C. at 760 mmHg)

¹H-NMR (400 MHz, C₆D₆, 25° C.): δ4.69 (s, 8H, Mo(C₆H₄(C(CH₃)₃)₂)), 1.17 (s, 36H, Mo(C₆H₄(C(CH₃)₃)₂))

### <Example 3> Preparation of bis-1-isopropyl-3,5-dimethyllbenzene-molybdenum: (η⁶-1-ⁱPr-3,5-Me₂C₆H₃)₂Mo

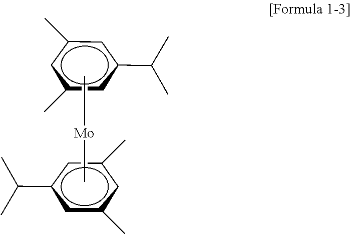

A flame-dried 2-liter Schlenk flask was charged with about 55 g (0.19 mole) of bis-toluene-molybdenum ((η⁶-MeC₆H₅)₂Mo) represented by Formula 1-4 of Comparative Example 1 described below and about 300 g of 1-isopropyl-3,5-dimethylbenzene (C₁₁H₁₆), which was maintained at room temperature. A cooler was connected to the flask, and the mixture in the flask was heated to 180° C. and then stirred for 12 hours. Upon completion of the reaction, the salt formed during the reaction was removed through filtration, and the solvent and volatile side reactants were distilled off under a reduced pressure to obtain about 47 g (yield: about 63% based on MoCl₅) of a green liquid represented by Formula 1-3.

Density: 1.32 g/mole (at 25° C.)

Boiling point (bp) 132° C. (0.5 Torr) (338° C. at 760 mmHg)

¹H-NMR (400 MHz, C₆D₆, 25° C.): 64.51 (s, 4H, Mo((CH₃)₂ CH—C₆H₃—(CH₃)₂)), δ4.40 (s, 2H, Mo((CH₃)₂CH—C₆H₃—(CH₃)₂)), δ2.31, 2.29, 2.27 (m, 2H, Mo((CH₃)₂CH—C₆H₃—(CH₃)₂)), δ1.96 (s, 12H, Mo((CH₃)₂CH—C₆H₃—(CH₃)₂)), δ1.17, 1.15 (d, 12H, Mo((CH₃)₂CH—C₆H₃—(CH₃)₂))

### <Comparative Example 1> Bis-toluene-molybdenum: (η⁶-MeC₆H₅)₂Mo

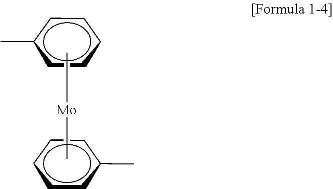

Bis-toluene-molybdenum ((η⁶-MeC₆H₅)₂Mo) represented by Formula 1-4 (SPCI Co., Ltd.) was purchased and used.

### <Comparative Example 2> Bis-ethylbenzene-molybdenum: (η⁶-EtC₆H₅)₂Mo

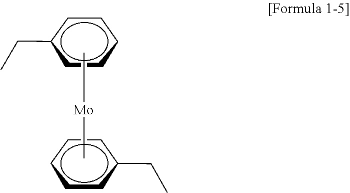

Bis-ethylbenzene-molybdenum ((η⁶-EtC₆H₅)₂Mo) represented by Formula 1-5 (Strem Chemicals, Inc.) was purchased and used.

### TEST EXAMPLE

### <Test Example 1> Structural Analysis of the Molybdenum Precursor Compounds

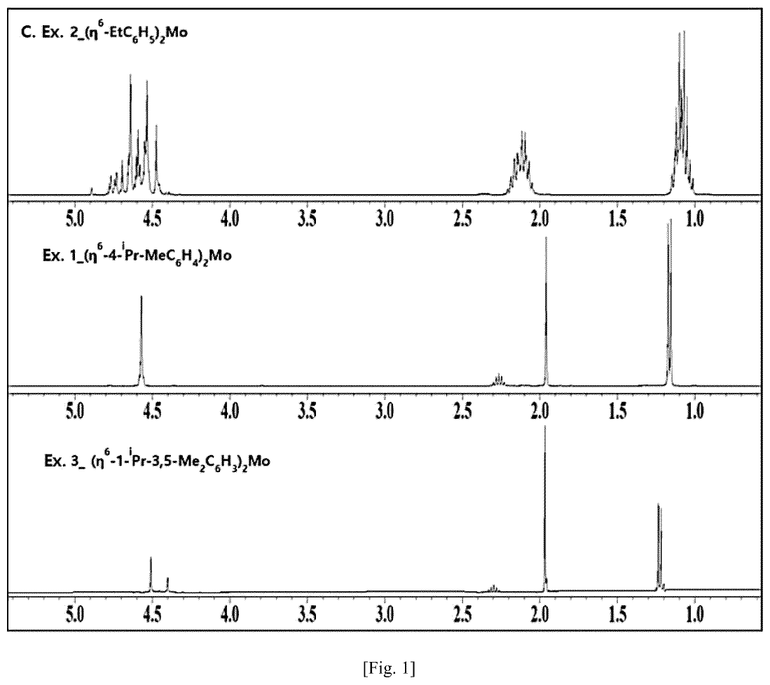

¹H-NMR analysis was carried out to analyze the structure of the molybdenum precursor compounds prepared in Examples 1 and 3 and the molybdenum precursor compound prepared in Comparative Example 2. The results are shown in Table 1 below and FIG. 1.

TABLE 1

| | Ex. 1 | | | |
|---|---|---|---|---|
| | Mo((CH₃)₂CH— | Mo((CH₃)₂CH— | Mo((CH₃)₂CH— | Mo((CH₃)₂CH— |
| | C₆H₄—CH₃) | C₆H₄—CH₃) | C₆H₄—CH₃) | C₆H₄—CH₃) |
| Chemical shift | δ 1.17, 1.15 | δ 2.46, 2.28, 2.26 | δ 4.56 | δ 1.96 |
| Peak multiplicity | D | m | s | s |
| | (Doublet) | (Multiplet) | (Singlet) | (Singlet) |

As can be seen from FIG. 1 and Table 1, since the molybdenum precursor compound of Comparative Example 2 had a composition (mixture structure) of various structures due to structural isomers, the chemical shift and peak multiplicity of hydrogen (proton) did not appear clearly in the ¹H-NMR analysis. In contrast, the molybdenum precursor compound prepared in Example 1 of the present invention was confirmed to have one composition in the ¹H-NMR analysis, and the chemical shifts and peak multiplicity appeared clearly as well.

It is confirmed from the results of structural analysis of the molybdenum precursor compounds that the molybdenum precursor compounds of Examples 1 and 3 are precursors of high purity sufficient to be applied to an ALD process. The molybdenum precursor compounds of the Examples can be used for the purpose of forming various films such as a molybdenum-containing metal film, a molybdenum-containing oxide film, a molybdenum-containing carbide film, a molybdenum-containing sulfide film, and a molybdenum-containing nitride film.

### <Test Example 2> Thermal Characteristic Analysis of the Molybdenum Precursor Compounds

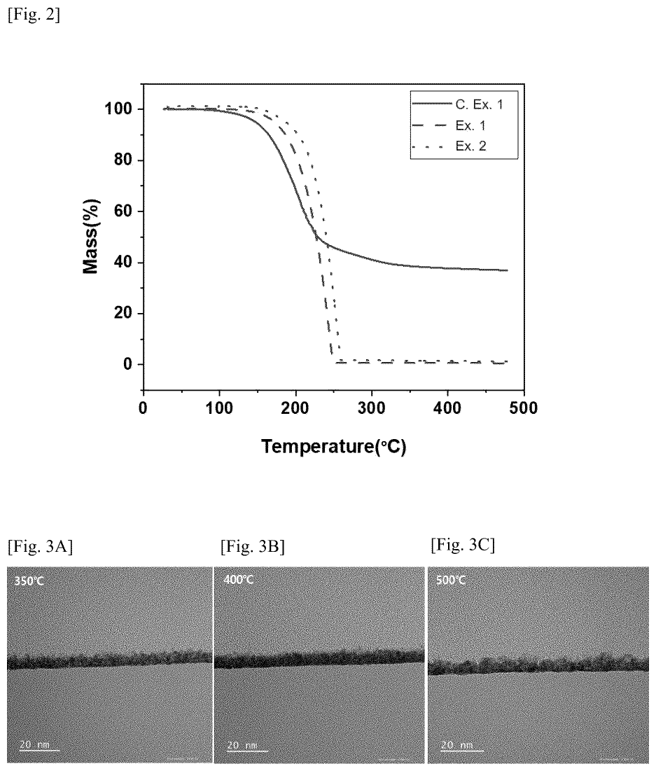

Thermogravimetric analysis (TGA) was carried out to analyze the thermal characteristics of the molybdenum precursor compounds prepared in Examples 1 and 3 and the molybdenum precursor compound of Comparative Example 1. The results are shown in Table 2 below and FIG. 2

For thermogravimetric analysis (TGA), the change in weight of the molybdenum precursor compound was measured while the temperature was raised from room temperature to about 500° C. at a temperature elevation rate of about 10° C./minute in a nitrogen (N₂) atmosphere.

Specifically, the vaporization initiation temperature (° C.) of the molybdenum precursor compound, TG₅₀ (° C.), which is the temperature when the weight reduction of the molybdenum precursor compound is 50%, W₅₀₀ (% by weight), which is a residual weight at 500° C., and WR₅₀₀(%), which is a weight residual ratio at 500° C., were measured.

Here, WR₅₀₀(%), which is a weight residual ratio at 500° C., may be calculated from the following Equation 1.

$$Weight residual ratio ( {WR}_{500} , \% ) = \frac{{W}_{25} - {W}_{500}}{{W}_{25}} \times 100 \qquad [ Equation 1 ]$$

In Equation 1,
W₂₅ is the initial weight (wt %) of the molybdenum precursor compound at 25° C., and
W₅₀₀ is the weight (wt %) of the molybdenum precursor compound at 500° C. as the temperature is raised from 25° C. to 500° C. at a temperature elevation rate of 10° C./minute.

TABLE 2

| | Vaporization | | | |
|---|---|---|---|---|
| | initiation | TG₅₀ | W₅₀₀ | WR₅₀₀ |
| | temperature (° C.) | (° C.) | (wt %) | (%) |
| Example 1 | 209.61 | 226.88 | 0.56 | 99.44 |
| Example 3 | 212.76 | 240.17 | 1.18 | 98.82 |
| Comparative | 161 | 228.86 | 36.9 | 63.1 |
| Example 1 | | | | |

As can be seen from FIG. 2, in the molybdenum precursor compound of Comparative Example 1, a lot of residues were left due to poor thermal stability, which is not suitable for use in a CVD or ALD process. In contrast, in the molybdenum precursor compounds prepared in Examples 1 and 3, residues were volatilized without decomposition, making them suitable as a precursor for use in a CVD or ALD process.

In addition, as can be seen from Table 2, most of the molybdenum precursor compounds of Examples 1 and 3 of the present invention were vaporized at about 209° C. to 213° C., and TG₅₀ (° C.), which is the temperature when the weight reduction of the molybdenum precursor compound is 50%, was about 226.88° C.

In addition, in the molybdenum precursor compounds prepared in Examples 1 and 3, W₅₀₀ (% by weight), which is a residual weight of the molybdenum precursor compound at 500° C., was about 0.56% by weight to 1.18% by weight. In the molybdenum precursor compound of Comparative Example 1, W₅₀₀ (% by weight), which is a residual weight of the molybdenum precursor compound at 500° C., was about 36.9% by weight, indicating a significant increase as compared with the molybdenum precursor compounds of Examples 1 and 3.

Meanwhile, in the molybdenum precursor compounds prepared in Examples 1 and 3, the weight residual ratio (WR₅₀₀) at 500° C. was about 98.82% to 99.44%. In the molybdenum precursor compound of Comparative Example 1, the weight residual ratio (WR₅₀₀) was significantly reduced to about 63.1%.

Accordingly, it was confirmed that the molybdenum precursor compounds of the present invention exhibit excellent volatility and that, in particular, they are excellent precursors for forming various molybdenum-containing films such as a molybdenum-containing metal film, a molybdenum-containing oxide film, a molybdenum-containing carbide film, a molybdenum-containing sulfide film, and a molybdenum-containing nitride film in a temperature range of 300° C. to 500° C.

### <Test Example 3> Deposition Characteristics of the Molybdenum Precursor Compounds with Ammonia

The molybdenum precursor compound prepared in Example 1 was used in an ALD process. Ammonia gas (NH₃) was used as a reaction gas to deposit a molybdenum-containing nitride film.

First, a silicon oxide substrate (board) (1,000 Å) was used as a substrate to prepare a molybdenum-containing nitride film. The silicon oxide substrate was a silicon oxide substrate from which organic substances had been removed by washing the surface of the silicon oxide substrate with flowing distilled water (DI-water) for the purpose of removing organic substances from the surface of the silicon oxide substrate.

In order to deposit a molybdenum-containing nitride film, the ALD cycle was fixed to 100 times, and the temperature of the substrate was set to 350° C., 400° C., and 500° C. to check the characteristics of the molybdenum-containing nitride film with respect to the temperature of the substrate.

The molybdenum precursor compounds were each put in a container made of stainless steel and heated to a temperature of about 120° C. for use. In such an event, the process pressure of the reactor was 1.8 Torr, argon (Ar) gas as a carrier gas flowed at a flow rate of about 200 sccm, and ammonia (NH₃) flowed at the flow rate of 400 sccm.

In order to check the optimized resistivity characteristics of each molybdenum-containing nitride film,
the ALD gas supply cycle was repeated 100 times to form a molybdenum-containing nitride film, in which the molybdenum precursor compound was supplied for about 5 seconds (precursor compound supply step); argon (Ar) gas was supplied for about 10 seconds to remove the molybdenum precursor compound (gas) remaining in the reactor (precursor compound purge step); NH₃ was supplied as a reaction gas for about 20 seconds (NH₃ supply step); and argon (Ar) gas was supplied for about 10 seconds to remove NH₃ remaining in the reactor (NH₃ purge step).

The sheet resistivity (μΩ/sq) of the molybdenum-containing nitride film deposited on the silicon oxide thin film substrate was measured using a 4PPS (4-point probe system), and the thickness of the molybdenum-containing nitride film was measured using a transmission electron microscope (TEM). The resistivity (μΩ·cm) was calculated from the thickness and sheet resistance of the molybdenum-containing nitride film.

In such an event, the resistivity (μΩ·cm) may be represented by the following Equation 2:

Resistivity (μΩ·cm)=sheet resistance (Ω/sq)×thickness of the film (×10⁻⁸, cm) 2

The thickness of the molybdenum-containing nitride film formed by the ALD method using the molybdenum precursor compound prepared in Example 1 and ammonia (NH₃) was measured to be 74.3 Å, 76.3 Å, and 91.5 Å, respectively, at the temperature of the substrate of, for example, 350° C., 400° C., and 500° C. The results of the TEM analysis are shown in FIG. 3.

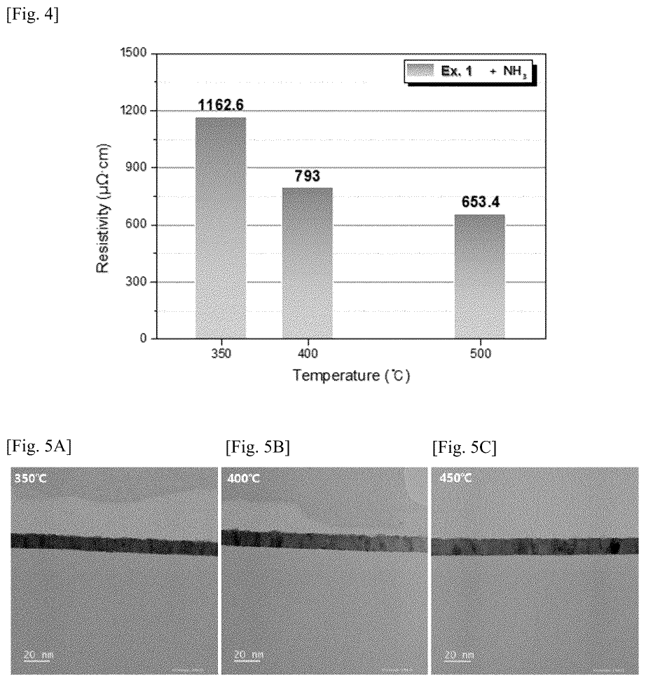

In addition, the resistivity (pμΩ·cm) of the molybdenum-containing nitride film formed by the ALD method using the molybdenum precursor compound prepared in Example 1 and ammonia (NH₃) was calculated. The results are shown in Table 3 and FIG. 4.

TABLE 3

| Deposition | Sheet resistance | | Resistivity |
|---|---|---|---|
| temp. (° C.) | (Q/sq) | Film thickness (Å) | (μΩ · cm) |
| 350 | 1,570 | 74.3 | 1162.6 |
| 400 | 1,040 | 76.3 | 793.0 |
| 500 | 714 | 91.5 | 653.4 |

As can be seen from Table 3 and FIG. 4, the resistivity values of the molybdenum-containing nitride films formed at a substrate temperature of 350° C., 400° C., and 500° C. were about 1,162.6 μΩ·cm, about 793.0 μΩ·cm, and about 653.4 μΩ·cm, respectively, indicating very low resistivity values. This is advantageous for use as a gate electrode, a diffusion barrier layer, and a capacitor electrode in DRAM or NAND flashes and logic devices that require low resistivity.

### <Test Example 4> Deposition Characteristics of the Molybdenum Precursor Compounds with Ammonia (NH₃) Plasma

A plasma enhanced atomic layer deposition (PEALD) process was carried out using the molybdenum precursor compounds of Example 1 and Comparative Example 2.

In order to deposit the molybdenum-containing nitride film, an RF power of 500 W was applied to NH₃ as a nitrogen source to be used as a reaction gas.

First, a silicon oxide substrate (board) (1,000 Å) was used as a substrate to prepare a molybdenum-containing nitride film. The silicon oxide substrate was a silicon oxide substrate from which organic substances had been removed by washing the surface of the silicon oxide substrate with flowing distilled water (DI-water) for the purpose of removing organic substances from the surface of the silicon oxide substrate.

In order to deposit a molybdenum-containing nitride film, the PEALD cycle was fixed to 100 times, and the temperature of the substrate was set to 350° C., 400° C., and 450° C. to check the characteristics of the molybdenum-containing nitride film with respect to the temperature of the substrate.

The molybdenum precursor compound prepared in Example 1 was put in a container made of stainless steel and heated to a temperature of about 140° C. for use. In such an event, the process pressure of the reactor was 1.8 Torr, argon (Ar) gas as a carrier gas flowed at a flow rate of about 200 sccm, and ammonia (NH₃) flowed at the flow rate of 500 sccm. The RF power of 500 W was used for a plasma of 13.56 MHz.

In order to confirm the optimized resistivity characteristics of each molybdenum-containing nitride film, the PEALD gas supply cycle was repeated 100 times to form a molybdenum-containing nitride film, in which the molybdenum precursor compound was supplied for about 3 seconds (precursor compound supply step); argon (Ar) gas was supplied for about 10 seconds to remove the molybdenum precursor compound (gas) remaining in the reactor (precursor compound purge step); NH₃ was supplied as a reaction gas for about 20 seconds (NH₃ supply step); and argon (Ar) gas was supplied for about 10 seconds to remove NH₃ remaining in the reactor (NH₃ purge step).

The molybdenum precursor compound of Comparative Example 2 was tested under the same conditions, except that the ALD gas supply cycle was repeated 100 times to form a molybdenum-containing nitride film, in which the molybdenum precursor compound was supplied for about 15 seconds (precursor compound supply step); argon (Ar) gas was supplied for about 10 seconds to remove the molybdenum precursor compound (gas) remaining in the reactor (precursor compound purge step); NH₃ was supplied as a reaction gas for about 20 seconds (NH₃ supply step); and argon (Ar) gas was supplied for about 15 seconds to remove NH₃ remaining in the reactor (NH₃ purge step).

The sheet resistivity (μΩ/sq) of the molybdenum-containing nitride film deposited on the silicon oxide thin film substrate was measured using a 4PPS (4-point probe system), and the thickness thereof was measured using a TEM.

The thickness of the molybdenum-containing nitride film formed by the PEALD method using the molybdenum precursor compound prepared in Example 1 and ammonia (NH₃) plasma was measured to be about 116.2 Å, about 127.2 Å, and about 127.3 Å, respectively, at the temperature of the substrate of, for example, 350° C., 400° C., and 450° C. The results of the TEM analysis are shown in FIG. 5.

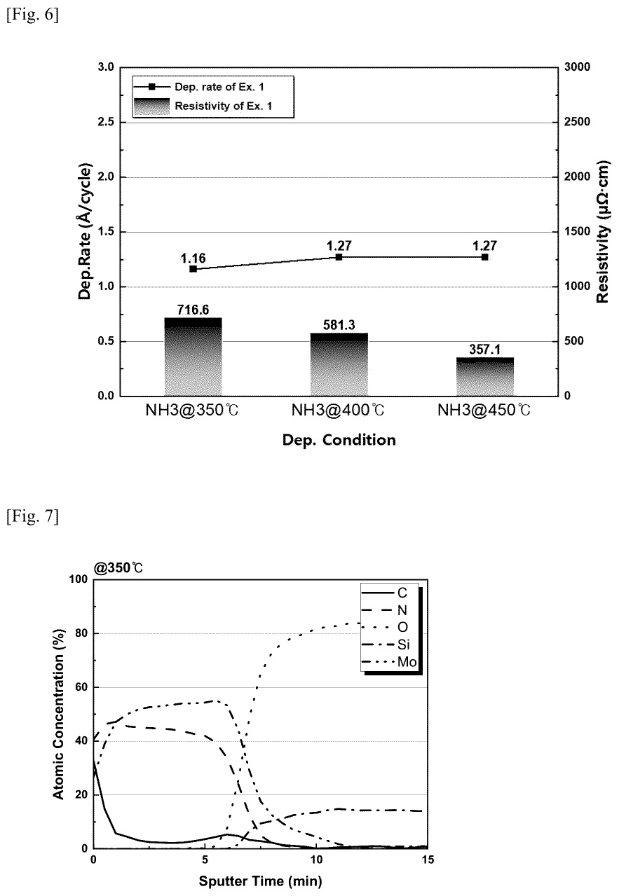

In addition, the deposition rate of the molybdenum-containing nitride film formed by the PEALD method using the molybdenum precursor compound prepared in Example 1 and ammonia (NH₃) plasma was about 1.16 Å/cycle, about 1.27 Å/cycle, and about 1.27 Å/cycle, respectively. The resistivity (μΩ·cm) was calculated from the sheet resistance. The results are shown in Table 4 and FIG. 6.

TABLE 4

| Deposition | Sheet resistance | | Resistivity |
|---|---|---|---|
| temp. (° C.) | (Q/sq) | Film thickness (Å) | (μΩ · cm) |
| 350 | 616.7 | 116.2 | 716.6 |
| 400 | 456.9 | 127.2 | 581.3 |
| 450 | 280.8 | 127.3 | 357.1 |

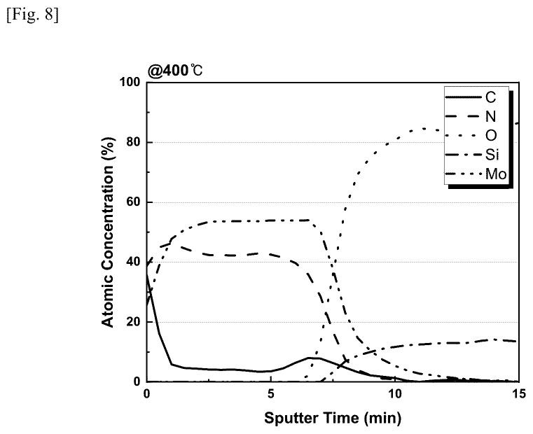

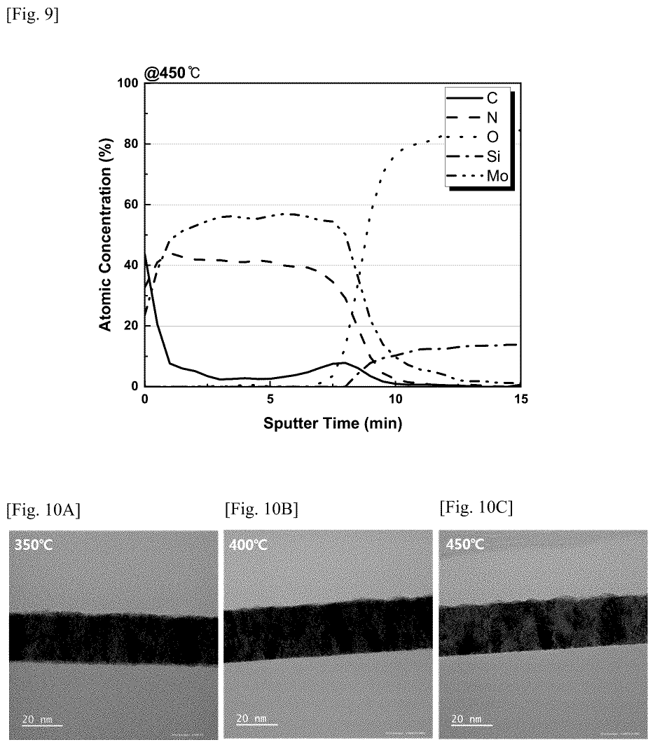

In addition, the element content (%) of the molybdenum-containing nitride film at each temperature was measured by AES (Auger electron spectroscopy). The results are shown in Table 5 and FIGS. 7 to 9.

TABLE 5

| Deposition | AES atomic concentration (%) (at sputter time of 2.5 min) | | | | |
|---|---|---|---|---|---|
| temp. (° C.) | C | N | O | Si | Mo |
| 350 | 2.5 | 44.9 | 0 | 0 | 52.6 |
| 400 | 4.2 | 42.4 | 0 | 0 | 53.4 |
| 450 | 3.5 | 41.7 | 0.2 | 0 | 54.6 |

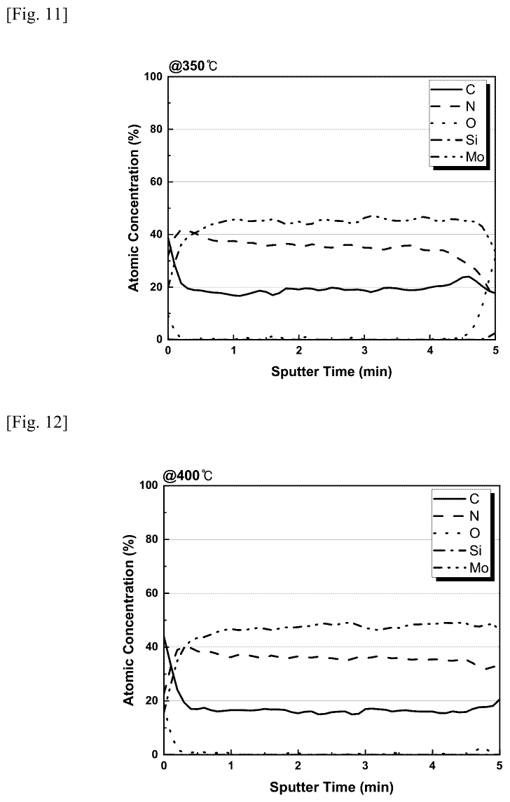

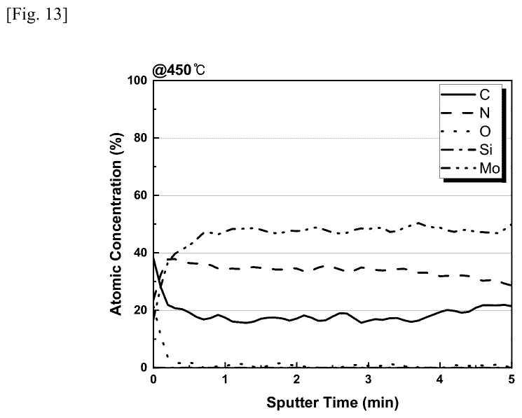

Meanwhile, the thickness of the molybdenum-containing nitride film formed by the PEALD method using the molybdenum precursor compound of Comparative Example 2 and ammonia (NH₃) plasma was measured to be about 240.3 Å, about 250.1 Å, and about 243.3 Å, respectively, at the temperature of the substrate of, for example, 350° C., 400° C., and 450° C. The results of the TEM analysis are shown in FIG. 10. In addition, the element content (%) of the molybdenum-containing nitride film at each temperature was measured by AES. The results are shown in Table 6 and FIGS. 11 to 13.

TABLE 6

| Deposition | AES atomic concentration (%) (at sputter time of 2.5 min) | | | | |
|---|---|---|---|---|---|
| temp. (° C.) | C | N | O | Si | Mo |
| 350 | 19.8 | 35.0 | 0 | 0 | 45.3 |
| 400 | 15.8 | 35.9 | 0 | 0 | 48.3 |
| 450 | 17.8 | 35.1 | 0 | 0 | 47.1 |

As can be seen from the results of the film component analysis by AES in Tables 5 and 6, FIGS. 7 to 9, and FIGS. 11 to 13, the content of carbon in the molybdenum-containing nitride film formed by the PEALD method using the molybdenum precursor compound prepared in Example 1 and ammonia (NH₃) plasma was significantly lower than that in the molybdenum-containing nitride film formed by the PEALD method using the molybdenum precursor compound of Comparative Example 2 and ammonia (NH₃) plasma.

In general, if the content of carbon is high, it may cause problems such as deterioration in electrical properties and a decrease in work function. The molybdenum-containing film formed using the molybdenum precursor compound prepared in Example 1 can solve the above problems.

In addition, as can be seen from Table 4, the resistivity values of the molybdenum-containing nitride film formed by the PEALD method using the molybdenum precursor compound prepared in Example 1 and ammonia (NH₃) plasma at a substrate temperature of 350° C., 400° C., and 500° C. were about 716.6 μΩ·cm, about 581.3 μΩ·cm, and about 357.1 μΩ·cm, respectively, indicating very low resistivity values.

In sum, according to the method for forming a molybdenum-containing film using the molybdenum precursor compound according to an embodiment of the present invention, a molybdenum-containing film could be readily deposited by ALD, and it was possible to form a molybdenum-containing film having a low content of carbon and a low resistivity value.

In particular, according to the method for forming a molybdenum-containing film using the molybdenum precursor compound according to an embodiment of the present invention, a film having a desired thickness and a low resistivity of 1,200 μΩ·cm or less could be obtained at a temperature of 350° C. to 450° C. As a result, the content of carbon in the molybdenum-containing nitride film thus obtained was significantly improved as compared with the molybdenum-containing nitride film using the molybdenum precursor compound of Comparative Example 2.

In addition, in the case where a molybdenum-containing film is formed using the molybdenum precursor compound of the present invention, it can provide a low carbon content of 5% or less and a low resistivity of 1,200 μΩ·cm or less; thus, it can be widely used as a gate electrode, a diffusion barrier layer, and a capacitor electrode used in DRAM or NAND flashes and logic devices that require low resistivity.

1. A molybdenum precursor compound represented by the following Formula 1: 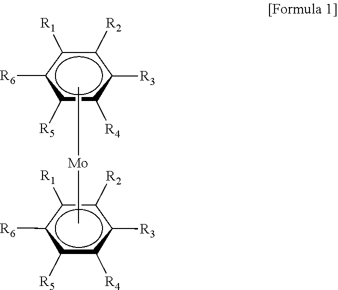
in Formula 1, R₁ to R₆ are each independently selected from the group consisting of hydrogen and a linear or branched C₁-C₈ alkyl group, provided that at least two of R₁ to R₆ are not hydrogen.

2. The molybdenum precursor compound of claim 1, wherein, in Formula 1, R₁ to R₆ are each independently selected from hydrogen, methyl, ethyl, propyl, isopropyl, butyl, isobutyl, tert-butyl, and pentyl, provided that at least two of R₁ to R₆ are not hydrogen.

3. The molybdenum precursor compound of claim 1, which is a compound represented by any one of the following Formulae 1-1 to 1-3:
[Formula 1-1]

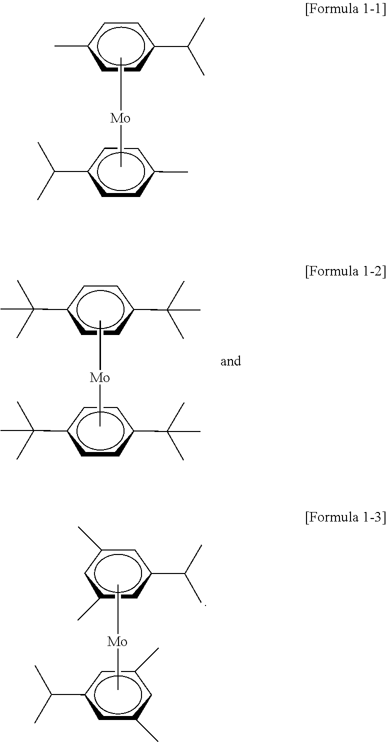

4. The molybdenum precursor compound of claim 1, wherein the molybdenum precursor compound has a TG₅₀ (° C.) of 180° C. to 350° C., in which TG₅₀ is a temperature when the weight of the molybdenum precursor compound is reduced by 50% while heated from room temperature to 500° C. at a temperature elevation rate of 10° C./minute in thermogravimetric analysis (TGA).

5. The molybdenum precursor compound of claim 4, wherein the molybdenum precursor compound has a weight residual ratio (WR₅₀₀) of 70% or more according to the following Equation 1:
$$Weight residual ratio ( {WR}_{500} , \% ) = \frac{{W}_{25} - {W}_{500}}{{W}_{25}} \times 100 \qquad [ Equation 1 ]$$
in Equation 1, W₂₅ is the initial weight (wt %) of the molybdenum precursor compound at 25° C., and W₅₀₀ is the weight (wt %) of the molybdenum precursor compound at 500° C. as the temperature is raised from 25° C. to 500° C. at a temperature elevation rate of 10° C./minute.

6. A composition for forming a molybdenum-containing film, which comprises the molybdenum precursor compound of claim 1.

7. The composition for forming a molybdenum-containing film according to claim 6, wherein the molybdenum precursor compound is a liquid.

8. The composition for forming a molybdenum-containing film according to claim 6, which is deposited using a molybdenum precursor compound represented by one of the following Formulae 1-1 to 1-3:

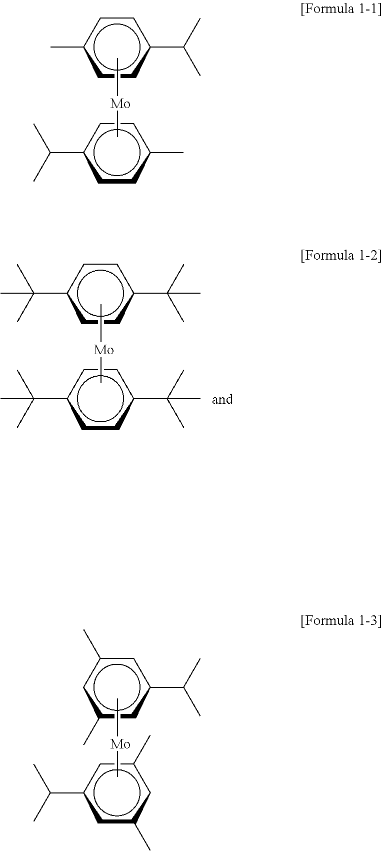

9. A molybdenum-containing film formed using the molybdenum precursor compound of claim 1.

10. The molybdenum-containing film of claim 9, wherein the molybdenum-containing film has a resistivity of 1,200 μΩ·cm or less.

11. The molybdenum-containing film of claim 9, wherein the molybdenum-containing film is at least one selected from the group consisting of a molybdenum-containing metal film, a molybdenum-containing oxide film, a molybdenum-containing carbide film, a molybdenum-containing sulfide film, and a molybdenum-containing nitride film.

12. A method for depositing a molybdenum-containing film, which comprises depositing a molybdenum-containing film on a substrate using the molybdenum precursor compound of claim 1.

13. The method for forming a silicon-containing film according to claim 12, wherein the deposition is carried out at a temperature of 300° C. to 550° C. by chemical vapor deposition (CVD) or atomic layer deposition (ALD).
